(19) United States
(12) Patent Application Publication
(10) Pub. No.: US 2025/0393123 A1
(43) Pub. Date: Dec. 25, 2025

(54) IMPACT-RESISTANT REINFORCED CARRIER

(71) Applicant: KINSUS INTERCONNECT TECHNOLOGY CORP., Taoyuan City (TW)

(72) Inventors: Ting-Hao LIN, Taoyuan City (TW); Chiao-Cheng CHANG, Taoyuan City (TW); Chien-Wei CHANG, Taoyuan City (TW)

(21) Appl. No.: 18/826,283

(22) Filed: Sep. 6, 2024

(30) Foreign Application Priority Data
Jun. 20, 2024 (TW) 113122994

(51) Int. Cl. H05K 1/11

(52) U.S. Cl. CPC H05K 1/115; H05K 1/111; H05K 2201/09036; H05K 2201/09563; H05K 2201/2009

(57) ABSTRACT

An impact-resistant reinforced carrier includes a substrate, a rigid insulated carrier sheet, metal pillars, a resin layer, and first and second circuit layers. The substrate has first through holes penetrating through upper and lower surfaces of the substrate. The rigid insulated carrier sheet has second through holes penetrating through first and second surfaces of the rigid insulated carrier sheet. The metal pillars are respectively in the second through holes. The resin layer covers the rigid insulated carrier sheet and the upper surface and has openings. The first circuit layer is on a portion of a surface of the resin layer, in the openings, and connected to the metal pillars. The second circuit layer is on a portion of the lower surface, in the first through holes, and connected to the metal pillars.

### CROSS-REFERENCE TO RELATED APPLICATION

This non-provisional application claims priority under 35 U.S.C. § 119(a) to patent application No. 113122994 filed in Taiwan, R.O.C. on Jun. 20, 2024, the entire contents of which are hereby incorporated by reference.

### BACKGROUND

### Technical Field

The instant disclosure is related to the field of chip packaging, especially to an impact-resistant reinforced carrier.

### Related Art

After the 2.0 D to 3.0 D packaging requirements for semiconductor chips arise, both the density and the complexity for the packaging greatly increase. To meet the packaging requirements for semiconductor chips, an interposer is introduced, and chiplets are packaged in a large-splicing manner.

However, due to the requirements of crisscross large-area splicing, the biggest challenge to advanced packaging is the flatness and stability of a material substrate, especially in the face of large temperature changes in the welding process. Currently, by increasing the thickness of a core plate, the industry can improve an assembly process, actual operation of products, and the coplanarity and stability of packaging planes. However, the core plate known to the inventor is made of glass fiber, which has the biggest disadvantage of thermal stability. As to the chiplets and large-area packaging configuration, high coplanarity and stability are necessary characteristics. Therefore, improving the temperature resistance and mechanical strength of carriers is a major challenge today.

### SUMMARY

As to the disadvantages of flatness and thermal stability, as known to the inventor, glass substrates are developed as the core plates. However, due to the requirements for the chiplets and large-area packaging configuration and the longer logistics time for delivering the carrier plates, the carrier plates may be impacted by external forces. Commonly, the corners of the carrier plates are found to have obvious cracks.

To address these issues, an impact-resistant reinforced carrier is provided. in some embodiments, the impact-resistant reinforced carrier comprises a substrate, at least one rigid insulated carrier sheet, a plurality of metal pillars, a resin layer, a first circuit layer, and a second circuit layer. The substrate has an upper surface and a lower surface, and the substrate has a plurality of first through holes penetrating through the upper surface and the lower surface. At least one portion of an outer periphery of each of the at least one rigid insulated carrier sheet is covered by a buffering layer, and each of the at least one rigid insulated carrier sheet has a plurality of second through holes penetrating through a first surface and a second surface of a corresponding one of the at least one rigid insulated carrier sheet.

The metal pillars are respectively in the second through holes. The resin layer is on the upper surface of the substrate and the at least one rigid insulated carrier sheet. The resin layer covers the at least one rigid insulated carrier sheet and the upper surface of the substrate. The resin layer has a plurality of openings. The first circuit layer is on a portion of a surface of the resin layer and in the openings, and the first circuit layer is connected to the metal pillars. The second circuit layer is on a portion of the lower surface of the substrate and in the first through holes, and the second circuit layer is connected to the metal pillars.

In some embodiments, the impact-resistant reinforced carrier comprises a plurality of the rigid insulated carrier sheets, a plurality of positioning regions is defined on the upper surface of the substrate, and the rigid insulated carrier sheets are on the positioning regions, respectively.

In some embodiments, the impact-resistant reinforced carrier comprises a plurality of the rigid insulated carrier sheets, and the rigid insulated carrier sheets are arranged and assembled with each other to form a rigid insulated carrier sheet assembly.

In some embodiments, each of the at least one rigid insulated carrier sheet comprises a plurality of recesses and a plurality of protrusions, and the buffering layer is in the recesses and coplanar with the protrusions.

More specifically, in some embodiments, the recesses are at four corners of each of the at least one rigid insulated carrier sheet.

In some embodiments, the buffering layer covers the outer periphery of each of the at least one rigid insulated carrier sheet.

In some embodiments, positions of the openings correspond to positions of the second through holes, respectively.

In some embodiments, the first surface of each of the at least one rigid insulated carrier sheet is further provided with a third circuit layer, and the third circuit layer is connected to the metal pillars in the second through holes and the first circuit layer.

More specifically, in some embodiments, the second surface of each of the ceramic plates is further provided with a fourth circuit layer, and the fourth circuit layer is connected to the metal pillars in the second through holes and the second circuit layer.

In some embodiments, the impact-resistant reinforced carrier further comprises a first solder mask layer, a first bonding pad layer, a second solder mask layer, and a second bonding pad layer. The first solder mask layer is on the resin layer and has a plurality of first bonding pad openings, and the first bonding pad layer is in the first bonding pad openings and electrically connected to the first circuit layer. The second solder mask layer is on the lower surface of the substrate and has a plurality of second bonding pad openings, and the second bonding pad layer is in the second bonding pad openings and electrically connected to the second circuit layer. The first bonding pad layer comprises a plurality of first bonding pads protruding out of the first solder mask layer, the second bonding pad layer comprises a plurality of second bonding pads protruding out of the second solder mask layer, and a first pitch between the first bonding pads is less than a second pitch between the second bonding pads.

Specifically, in some embodiments, the impact-resistant reinforced carrier further comprises a first protection layer, a first redistribution layer, a second protection layer, and a second redistribution layer. The first protection layer is between the resin layer and the first solder mask layer, and the first protection layer covers the first circuit layer and has a plurality of first openings. The first redistribution layer is on a portion of the first protection layer and is in the first openings, and the first redistribution layer is connected to the first circuit layer and the first solder mask layer. The second protection layer is between the lower surface of the substrate and the second solder mask layer, and the second protection layer covers the second circuit layer and has a plurality of second openings. The second redistribution layer is on a portion of the second protection layer and is in the second openings, and the second redistribution layer is connected to the second circuit layer and the second solder mask layer.

Specifically, in some embodiments, positions of the first openings correspond to positions of the first bonding pad openings, respectively, and positions of the second openings correspond to positions of the second bonding pad openings, respectively.

According to one or some embodiments, by covering the buffering layer on at least one portion of the rigid insulated carrier sheet and by covering the resin layer on the rigid insulated carrier sheet, an advanced buffering effect can be provided. Consequently, during delivery or testing, the carrier can be prevented having cracks when the carrier is subjected to an external force.

### BRIEF DESCRIPTION OF THE DRAWINGS

The disclosure will become more fully understood from the detailed description given herein below for illustration only, and thus not limitative of the disclosure, wherein:

FIG. 1 illustrates a partial top view of an impact-resistant reinforced carrier according to a first embodiment of the instant disclosure;

FIG. 2 illustrates a partial cross-sectional view of the impact-resistant reinforced carrier according to the first embodiment of the instant disclosure;

FIG. 3 illustrates a partial top view of an impact-resistant reinforced carrier according to a second embodiment of the instant disclosure;

FIG. 4 illustrates a partial top view of an impact-resistant reinforced carrier according to a third embodiment of the instant disclosure;

FIG. 5 illustrates a partial top view of an impact-resistant reinforced carrier according to a fourth embodiment of the instant disclosure;

FIG. 6 and FIG. 7 illustrate schematic views of the manufacturing process of the rigid insulated carrier sheet; and

FIG. 8 illustrates a partial cross-sectional view of an anti-warpage carrier according to a fifth embodiment of the instant disclosure.

### DETAILED DESCRIPTION

It should be understood that, when an element is referred to as being “disposed on” or “connected to” another element, the element may be directly on the another element, or one or more intervening elements may be present so that the element is connected to the another element through the one or more intervening elements. On the contrary, when an element is referred to as being “directly disposed on/directly connected on” or “directly disposed to/directly connected to” another element, it can be clearly understood that there are no intervening elements between the two elements.

Furthermore, in the following descriptions, it will be understood that, although the terms “first,” “second,” “third,” etc. may be used herein to describe various elements, components, regions, layers, or portions, these terms are only used to distinguish these elements, components, regions, layers, or sections, rather than being used to represent the definite order of these elements, components, regions, layers, or portions. Moreover, it will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. In other words, these terms only represent a relative position relationship between the described components, not an absolute position relationship between the described components.

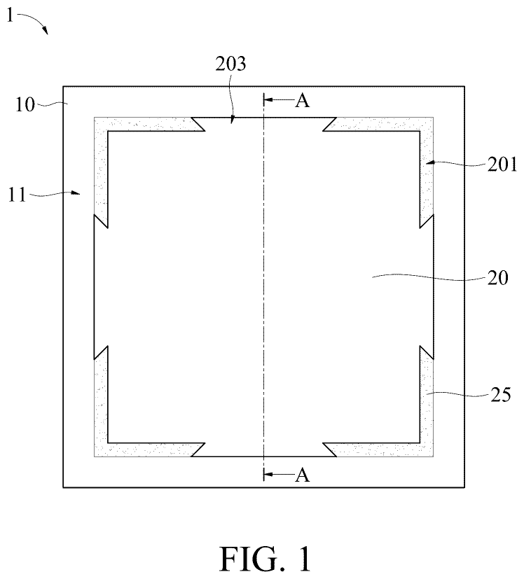

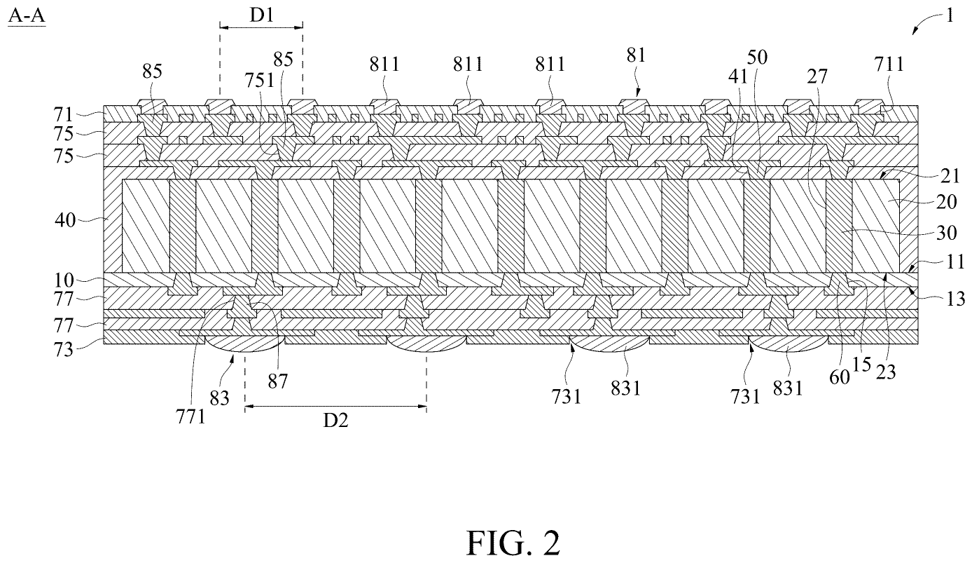

FIG. 1 illustrates a partial top view of an impact-resistant reinforced carrier according to a first embodiment of the instant disclosure. FIG. 2 illustrates a partial cross-sectional view of the impact-resistant reinforced carrier according to the first embodiment of the instant disclosure. As shown in FIG. 1 and FIG. 2, in some embodiments, the impact-resistant reinforced carrier 1 comprises a substrate 10, a rigid insulated carrier sheet 20, a plurality of metal pillars 30, a resin layer 40, a first circuit layer 50, and a second circuit layer 60. To illustrate the overall structure of the impact-resistant reinforced carrier 1, in FIG. 1, the metal pillars 30, the resin layer 40, the first circuit layer 50, and the second circuit layer 60 are omitted.

The substrate 10 has an upper surface 11 and a lower surface 13. The substrate 10 has a plurality of first through holes 15 penetrating through the upper surface 11 and the lower surface 13. At least one portion of an outer periphery of the rigid insulated carrier sheet 20 is covered by a buffering layer 25, and the rigid insulated carrier sheet 20 has a plurality of second through holes 27 penetrating through a first surface 21 and a second surface 22 of the rigid insulated carrier sheet 20. Specifically, in some embodiments, the rigid insulated carrier sheet 20 comprises a plurality of recesses 201 and a plurality of protrusions 203, and the buffering layer 25 is in the recesses 201 and coplanar with the protrusions 203. For example, the recesses 201 are at four corners of the rigid insulated carrier sheet 20. Through the filling of the buffering layer 25, the rigid insulated carrier sheet 20 can be formed as a rectangular-shaped structure. In this embodiment, the rigid insulated carrier sheet 20 may be a glass plate, a ceramic plate, or the like.

As shown in FIG. 2, the metal pillars 30 are respectively in the second through holes 27. The resin layer 40 is on the upper surface 11 of the substrate 10 and the rigid insulated carrier sheet 20, the resin layer 40 covers the rigid insulated carrier sheet 20 and the upper surface 11 of the substrate 10, and the resin layer 40 has a plurality of openings 41. The first circuit layer 50 is on a portion of a surface of the resin layer 40 and in the openings 41, and the first circuit layer 50 is connected to the metal pillars 30. The second circuit layer 60 is on a portion of the lower surface 13 of the substate 10 and in the first through holes 15, and the second circuit layer 60 is connected to the metal pillars 30.

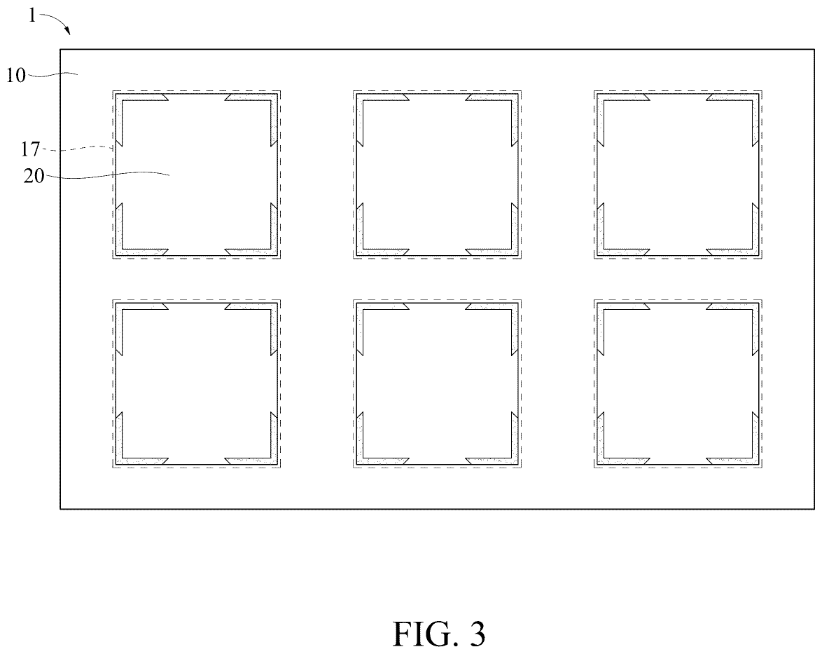

FIG. 3 illustrates a partial top view of an impact-resistant reinforced carrier according to a second embodiment of the instant disclosure. Likewise, to illustrate the overall structure of the impact-resistant reinforced carrier 1, in FIG. 3, the metal pillars 30, the resin layer 40, the first circuit layer 50, and the second circuit layer 60 are omitted. Please refer to FIG. 3 and also FIG. 1. The difference between the second embodiment and the first embodiment lies in that, in the second embodiment, the impact-resistant reinforced carrier 1 comprises a plurality of the rigid insulated carrier sheets 20. The rigid insulated carrier sheets 20 are configured to have smaller sizes (as compared with the rigid insulated carrier sheet 20 of the first embodiment) and are arranged on the substrate 10. A plurality of positioning regions 17 is defined on the upper surface 11 of the substrate 10, and the rigid insulated carrier sheets 20 are on the positioning regions 17, respectively.

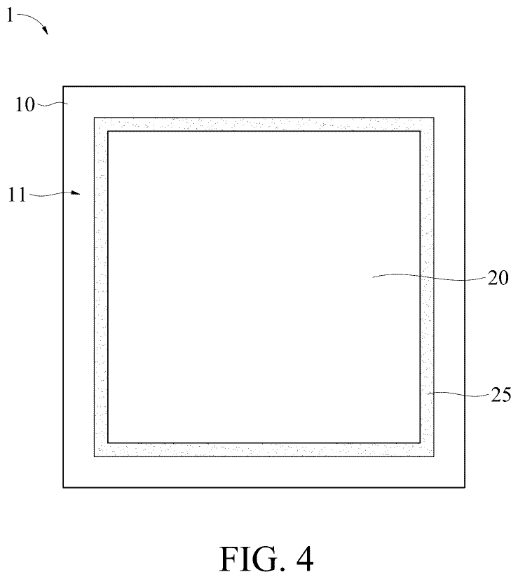

FIG. 4 illustrates a partial top view of an impact-resistant reinforced carrier according to a third embodiment of the instant disclosure. Likewise, to illustrate the overall structure of the impact-resistant reinforced carrier 1, in FIG. 4, the metal pillars 30, the resin layer 40, the first circuit layer 50, and the second circuit layer 60 are omitted. Please refer to FIG. 4 and also FIG. 1. The difference between the third embodiment and the first embodiment lies in that, in the third embodiment, the buffering layer 25 covers the outer periphery of each of the rigid insulated carrier sheets 20.

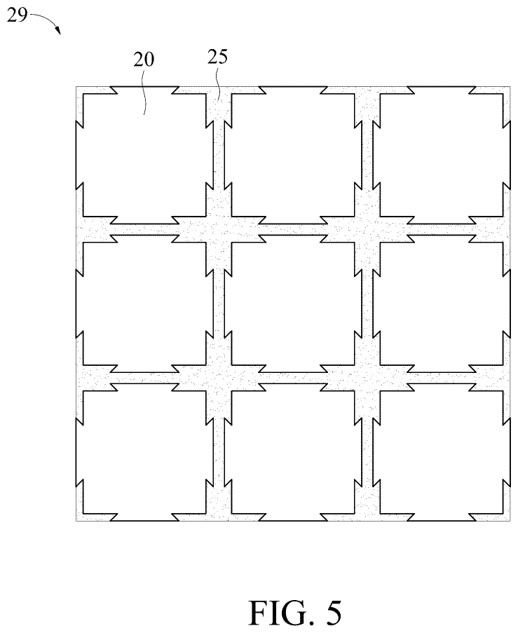

FIG. 5 illustrates a partial top view of an impact-resistant reinforced carrier according to a fourth embodiment of the instant disclosure. Likewise, to illustrate the overall structure of the anti-warpage carrier 1, in FIG. 5, the metal pillars 30, the resin layer 40, the first circuit layer 50, and the second circuit layer 60 are omitted. Please refer to FIG. 5 and also FIG. 1. In the fourth embodiment, the impact-resistant reinforced carrier 1 comprises a plurality of the rigid insulated carrier sheets 20 which are assembled with each other to form a rigid insulated carrier sheet assembly 29. Accordingly, the rigid insulated carrier sheets 20 are configured to have smaller sizes (as compared with the rigid insulated carrier sheet 20 of the first embodiment) so that the impact-resistant reinforced carrier 1 can be manufactured quickly.

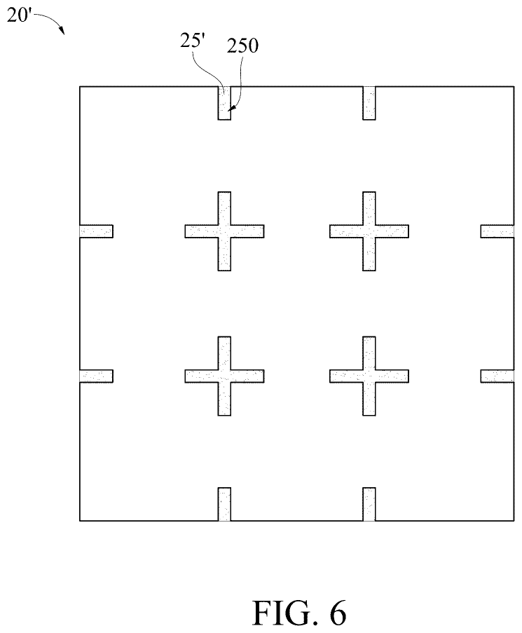

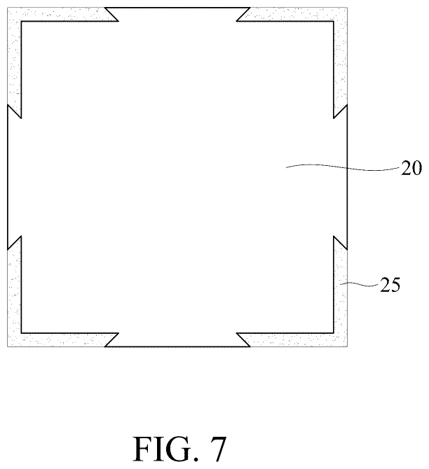

FIG. 6 and FIG. 7 illustrate schematic views of the manufacturing process of the rigid insulated carrier sheet. As shown in FIG. 6, in the manufacturing process of the rigid insulated carrier sheet 20, a large-sized rigid carrier plate 20′ is processed to have cutting lines 250 with desired sizes and shapes, and then a buffering layer material 25′ is applied to at least fill into the cutting lines 250. Next, as shown in FIG. 6 and FIG. 7, the rigid carrier plate 20′ is cut along the cutting lines 250 and the redundant buffering layer material 25′ is removed, so that the rigid insulated carrier sheet 20 covered by the buffering layer 25 can be provided. in this embodiment, the rigid insulated carrier sheet 20 is manufactured to have the shape of the rigid insulated carrier sheet 20 shown in the first embodiment; however, it is understood that, the shape of the rigid insulated carrier sheet 20 shown in FIG. 6 and FIG. 7 are provided just for illustrative purposes, not limitations to the instant disclosure.

Please refer to FIG. 2 again. In some embodiments, positions of the openings 41 may correspond to positions of the second through holes 27, respectively. Specifically, in some embodiments, the impact-resistant reinforced carrier 1 further comprises a first solder mask layer 71, a first bonding pad layer 81, a second solder mask layer 73, and a second bonding pad layer 83. The first solder mask layer 71 is on the resin layer 40 and has a plurality of first bonding pad openings 711. The first bonding pad layer 81 is in the first bonding pad openings 711 and electrically connected to the first circuit layer 50. The second solder mask layer 73 is on the lower surface 13 of the substrate 10 and has a plurality of second bonding pad openings 731. The second bonding pad layer 83 is in the second bonding pad openings 731 and electrically connected to the second circuit layer 60. The first bonding pad layer 81 comprises a plurality of first bonding pads 811 protruding out of the first solder mask layer 71. The second bonding pad layer 83 comprises a plurality of second bonding pads 831 protruding out of the second solder mask layer 73, and a first pitch D1 between the first bonding pads 811 is less than a second pitch D2 between the second bonding pads 831.

Specifically, in some embodiments, the impact-resistant reinforced carrier 1 further comprises a first protection layer 75, a first redistribution layer 85, a second protection layer 77, and a second redistribution layer 87. The first protection layer 75 is between the resin layer 40 and the first solder mask layer 71, and the first protection layer 75 covers the first circuit layer 50 and has a plurality of first openings 751. The first redistribution layer 85 is on a portion of the first protection layer 75 and is in the first openings 751, and the first redistribution layer 85 is connected to the first circuit layer 50 and the first solder mask layer 81. The second protection layer 77 is between the lower surface 13 of the substrate 10 and the second solder mask layer 73, and the second protection layer 77 covers the second circuit layer 60 and has a plurality of second openings 771. The second redistribution layer 87 is on a portion of the second protection layer 77 and is in the second openings 771, and the second redistribution layer 87 is connected to the second circuit layer 60 and the second solder mask layer 83.

More specifically, in some embodiments, positions of the first openings 751 correspond to positions of the first bonding pad openings 711, respectively, and positions of the second openings 771 correspond to positions of the second bonding pad openings 731, respectively. In this embodiment, the first protection layer 75, the first redistribution layer 85, the second protection layer 76, and the second redistribution layer 87 may be configured as one or several layers to be adapted to the layouts.

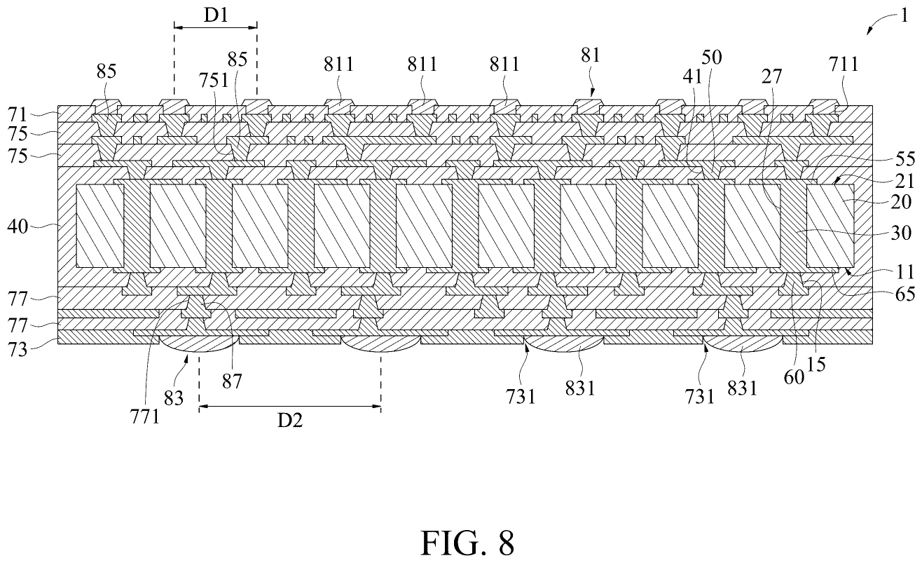

FIG. 8 illustrates a partial cross-sectional view of an impact-resistant reinforced carrier according to a fifth embodiment of the instant disclosure. Please refer to FIG. 8 and also FIG. 2. In the fifth embodiment, the first surface 21 of the rigid insulated carrier sheet 20 is further provided with a third circuit layer 55, and the third circuit layer 55 is connected to the metal pillars 30 in the second through holes 27 and the first circuit layer 50.

Moreover, in some embodiments, the second surface 23 of the rigid insulated carrier sheet 20 is further provided with a fourth circuit layer 65, and the fourth circuit layer 65 is connected to the metal pillars 30 in the second through holes 27 and the second circuit layer 60.

According to one or some embodiments, by covering the buffering layer 25 on at least one portion of the rigid insulated carrier sheet 20 and by covering the resin layer 40 on the rigid insulated carrier sheet 20, an advanced buffering effect can be provided. Consequently, during delivery or testing, the carrier can be prevented having cracks when the carrier is subjected to an external force.

Although the instant disclosure has been disclosed as above by way of embodiments, the embodiments are not intended to limit the scope of the instant disclosure, and persons having ordinary skills in the art may make some changes and modifications without departing from the spirit and scope of the instant disclosure, and therefore the scope of protection of the instant disclosure shall be subject to the scope of the instant disclosure as defined in the appended claims.

What is claimed is:

1. An impact-resistant reinforced carrier comprising:
a substrate having an upper surface and a lower surface, wherein the substrate has a plurality of first through holes penetrating through the upper surface and the lower surface;
at least one rigid insulated carrier sheet, wherein at least one portion of an outer periphery of each of the at least one rigid insulated carrier sheet is covered by a buffering layer, each of the at least one rigid insulated carrier sheet has a plurality of second through holes penetrating through a first surface and a second surface of the corresponding one of the at least one rigid insulated carrier sheet;
a plurality of metal pillars in the second through holes, respectively;
a resin layer on the upper surface of the substrate and the at least one rigid insulated carrier sheet, wherein the resin layer covers the at least one rigid insulated carrier sheet and the upper surface of the substrate, and the resin layer has a plurality of openings;
a first circuit layer on a portion of a surface of the resin layer and in the openings, wherein the first circuit layer is connected to the metal pillars; and
a second circuit layer on a portion of the lower surface of the substrate and in the first through holes, wherein the second circuit layer is connected to the metal pillars.

2. The impact-resistant reinforced carrier according to claim 1, wherein the impact-resistant reinforced carrier comprises a plurality of the rigid insulated carrier sheets, a plurality of positioning regions are defined on the upper surface of the substrate, and the rigid insulated carrier sheets are on the positioning regions, respectively.

3. The impact-resistant reinforced carrier according to claim 1, wherein the impact-resistant reinforced carrier comprises a plurality of the rigid insulated carrier sheets, and the rigid insulated carrier sheets are arranged and assembled with each other to form a rigid insulated carrier sheet assembly.

4. The impact-resistant reinforced carrier according to claim 1, wherein each of the at least one rigid insulated carrier sheet comprises a plurality of recesses and a plurality of protrusions, and the buffering layer is in the recesses and coplanar with the protrusions.

5. The impact-resistant reinforced carrier according to claim 4, wherein the recesses are at four corners of each of the at least one rigid insulated carrier sheet.

6. The impact-resistant reinforced carrier according to claim 1, wherein the buffering layer covers the outer periphery of each of the at least one rigid insulated carrier sheet.

7. The impact-resistant reinforced carrier according to claim 1, wherein positions of the openings correspond to positions of the second through holes, respectively.

8. The impact-resistant reinforced carrier according to claim 1, wherein the first surface of each of the at least one rigid insulated carrier sheet is further provided with a third circuit layer, and the third circuit layer is connected to the metal pillars in the second through holes and the first circuit layer.

9. The impact-resistant reinforced carrier according to claim 8, wherein the second surface of each of the at least one rigid insulated carrier sheet is further provided with a fourth circuit layer, and the fourth circuit layer is connected to the metal pillars in the second through holes and the second circuit layer.

10. The impact-resistant reinforced carrier according to claim 1 further comprising a first solder mask layer, a first bonding pad layer, a second solder mask layer, and a second bonding pad layer, wherein the first solder mask layer is on the resin layer and has a plurality of first bonding pad openings, and the first bonding pad layer is in the first bonding pad openings and electrically connected to the first circuit layer; the second solder mask layer is on the lower surface of the substrate and has a plurality of second bonding pad openings, and the second bonding pad layer is in the second bonding pad openings and electrically connected to the second circuit layer; the first bonding pad layer comprises a plurality of first bonding pads protruding out of the first solder mask layer, the second bonding pad layer comprises a plurality of second bonding pads protruding out of the second solder mask layer, and a first pitch between the first bonding pads is less than a second pitch between the second bonding pads.

11. The impact-resistant reinforced carrier according to claim 10 further comprising a first protection layer, a first redistribution layer, a second protection layer, and a second redistribution layer, wherein the first protection layer is between the resin layer and the first solder mask layer, and the first protection layer covers the first circuit layer and has a plurality of first openings; the first redistribution layer is on a portion of the first protection layer and is in the first openings, and the first redistribution layer is connected to the first circuit layer and the first solder mask layer; the second protection layer is between the lower surface of the substrate and the second solder mask layer, and the second protection layer covers the second circuit layer and has a plurality of second openings; the second redistribution layer is on a portion of the second protection layer and is in the second openings, and the second redistribution layer is connected to the second circuit layer and the second solder mask layer.

12. The impact-resistant reinforced carrier according to claim 11, wherein positions of the first openings correspond to positions of the first bonding pad openings, respectively, and positions of the second openings correspond to positions of the second bonding pad openings, respectively.
